(19) United States
(12) Patent Application Publication
(10) Pub. No.: US 2008/0197503 A1
(43) Pub. Date: Aug. 21, 2008

(54) CHIP PACKAGE

(75) Inventor: Chi-Hsing Hsu, Taipei Hsien (TW)

Correspondence Address: J C PATENTS, INC., 4 VENTURE, SUITE 250, IRVINE, CA, 92618, US

(73) Assignee: VIA TECHNOLOGIES, INC., Taipei Hsien (TW)

(21) Appl. No.: 11/876,381

(22) Filed: Oct. 22, 2007

Related U.S. Application Data
(60) Provisional application No. 60/890,178, filed on Feb. 15, 2007.

(51) Int. Cl. H01L 23/49

(52) U.S. Cl. 257/763; 257/E23.024

(57) ABSTRACT

A chip package including a carrier, at least one chip disposed on the carrier, a plurality of wires electrically connecting the carrier and the chip, and an encapsulant wrapping the chip and the wires is provided. The chip has a semiconductor substrate, an interconnection structure, at least one first reference plane, at least one second reference plane, and at least one chip via, in which the first and second reference planes are respectively located on both sides of the semiconductor substrate, and the interconnection structure is located on the first reference plane and the semiconductor substrate. The chip via connects the first reference plane to the second reference plane. The chip package further includes at least one conductive bonding layer, which bonds the second reference plane to the carrier.

### CROSS-REFERENCE TO RELATED APPLICATION

This application claims the priority benefit of U.S. provisional application Ser. No. 60/890,178, filed on Feb. 15, 2007, all disclosures are incorporated therewith.

### BACKGROUND OF THE INVENTION

1. Field of the Invention

The present invention relates to an integrated circuit (IC). More particularly, the present invention relates to a package electrically connecting two sides of a chip to a carrier carrying the chip.

2. Description of Related Art

Due to the development of IC process technology, signal density of a chip increases. For a packaging type of wire bonding matching with a carrier, the chip is disposed on the carrier, and a plurality of wires are used to electrically connect the chip and the carrier. However, when the signal density of the chip increases, inductance coupling between wires generated by electromagnetic effect increases, such that signals are interfered by noise and crosstalk quite seriously as transmitting in wires during switching.

Therefore, in order to effective maintain transmission quality of the signal, a packaging type of flip chip bonding matching with the carrier has been adopted, and this packaging type can reduce the interference of noise and crosstalk. However, on the cost, the packaging type of flip chip bonding matching with the carrier is still higher than the packaging type of wire bonding matching with the carrier. Therefore, no matter for which one of the packaging types, it becomes an objective to be developed how to maintain the signal transmission quality while reducing the manufacturing cost.

### SUMMARY OF THE INVENTION

Accordingly, the present invention is directed to provide a chip package for packaging a chip.

The present invention provides a chip package, which includes a carrier, at least one chip, at least one conductive bonding layer, at least one wire, and an encapsulant. The carrier has a first carrier surface. The chip has a semiconductor substrate, an interconnection structure, at least one first reference plane, at least one second reference plane, and at least one chip via. The semiconductor substrate has a first substrate surface and a second substrate surface opposite to the first substrate surface, and the first reference plane and the second reference plane are respectively located on the first substrate surface and the second substrate surface. The interconnection structure is located on the first reference plane and the first substrate surface and has at least one chip signal pad, and the chip via connects the first reference plane to the second reference plane. The conductive bonding layer bonds the second reference plane to the first carrier surface of the carrier. The wire connects the chip signal pad to the first carrier surface of the carrier. The encapsulant wraps the chip and the wire.

In order to make the aforementioned and other features and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a partial sectional view of a chip package according to an embodiment of the present invention.

FIG. 2 is an enlarged view of part A of FIG. 1.

FIG. 3 is a partial sectional enlarged view of a chip package according to another embodiment of the present invention.

### DESCRIPTION OF EMBODIMENTS

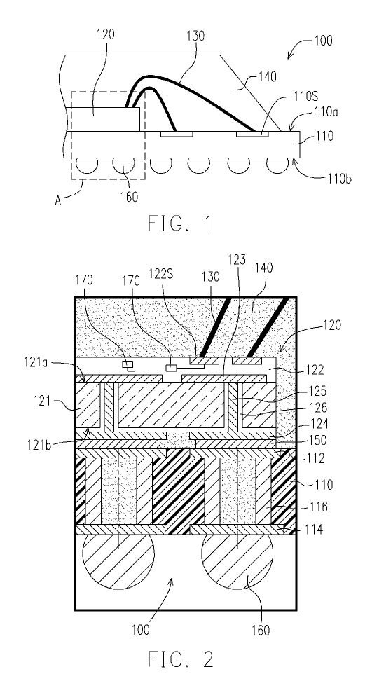

FIG. 1 is a partial sectional view of a chip package according to an embodiment of the present invention, and FIG. 2 is an enlarged view of part A of FIG. 1. Referring to FIGS. 1 and 2, a chip package 100 of an embodiment of the present invention includes a carrier 110, a chip 120, a plurality of wires 130, and an encapsulant 140. The chip 120 is disposed on the carrier 110, the wires 130 electrically connect the chip 120 to the carrier 110, and the encapsulant 140 wraps the chip 120 and the wires 130.

The chip 120 includes a semiconductor substrate 121 and an interconnection structure 122. The semiconductor substrate 121 is, for example, a silicon substrate, and has a first substrate surface 121a and a second substrate surface 121b opposite to the first substrate surface 121a, and the interconnection structure 122 is located on the first substrate surface 121a.

The interconnection structure 122 includes a plurality of chip signal pads 122s, which are composed of metal line of the interconnection structure 122 and are located on top of the interconnection structure 122. In addition, the carrier 110 has a plurality of carrier signal pads 110s located on a first carrier surface 110a of the carrier 110, and the wires 130 connect the carrier signal pads 110s and the chip signal pads 122s. Therefore, in the chip 120, an electronic device 170, such as a transistor or a capacitor, located on the first substrate surface 121a can be electrically connected to the carrier 110 through the interconnection structure 122 and the wires 130. The electronic device 170 can be formed by a semiconductor process, the electronic device 170 is not limited to an active device or a passive device, and the first substrate surface 121a can be considered as a chip active surface.

The chip 120 further includes a plurality of first reference planes 123, the first reference planes 123 are located on the first substrate surface 121a, and the interconnection structure 122 is located on the first substrate surface 121a and the first reference planes 123. Therefore, in the chip 120, the electronic device 170, such as a transistor or a capacitor, located on the first substrate surface 121a can be electrically connected to the first reference planes 123 through the interconnection structure 122.

The chip 120 further includes a plurality of second reference planes 124 and a plurality of chip vias 125. The second reference planes 124 are located on the second substrate surface 121b, and the chip vias 125 pass through an internal part of the semiconductor substrate 121, so as to respectively connect the first reference planes 123 to the second reference planes 124. In this embodiment, the chip 120 further has an insulation layer 126, for example a silicon oxide (SiO₂) layer, located between the semiconductor substrate 121 and the second reference planes 124 and between the semiconductor substrate 121 and the chip vias 125.

In this embodiment, the first reference planes 123 can include a ground plane, a power plane, or both, and the second reference planes 124 can be the ground plane or the power plane according to the first reference planes 123 electrically connected thereto. In addition, the second reference planes 124 can be a single layer, for example a gold layer, or a composite layer, for example a composite layer including a titanium (Ti) layer, a copper (Cu) layer, and a nickel (Ni) layer, or a composite layer including a Ti layer, a nickel-vanadium (Ni—V) layer, and a Cu layer. In addition, the reference planes 123 and 124 are annular shaped.

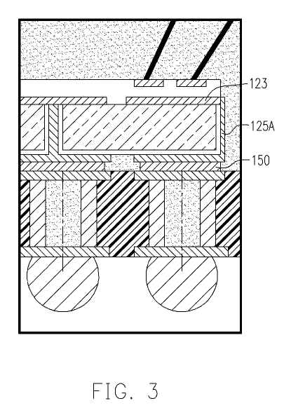

In this embodiment, the chip vias 125 pass through the internal part of the semiconductor substrate 121 to respectively connect the first reference planes 123 and the second reference planes 124. In another embodiment, as shown in FIG. 3, a chip via 125A can bypass an external side of the semiconductor substrate 121 to respectively connect the first reference planes 123 and the second reference planes 124.

Referring to FIGS. 1 and 2, the chip package 100 further includes a plurality of conductive bonding layers 150, and the conductive bonding layers 150 respectively bond the second reference planes 124 to the first carrier surface 110a of the carrier 110, so as to be electrically connected to the carrier 110. The material of the conductive bonding layers 150 can be solder, for example tin-silver-copper (Sn—Ag—Cu) alloy, Sn—Ag alloy, Sn—Cu alloy, or tin-lead (Sn—Pb) alloy, or can be a conductive adhesive.

Therefore, the reference planes 123 can be electrically connected to the carrier 110 without using the wires 130, instead, through the chip vias 125, the second reference planes 124, and the conductive bonding layers 150.

In this embodiment, the carrier 110 can have a plurality of first reference pads 112 located on the first carrier surface 110a of the carrier 110, and the conductive bonding layers 150 respectively bond the second reference planes 124 to the first reference pads 112. In addition, the carrier 110 further has a plurality of second reference pads 114 and a plurality of carrier vias 116, the second reference pads 114 are located on a second carrier surface 110b opposite to the first carrier surface 110a, and the carrier vias 116 respectively electrically connect the first reference pads 112 to the second reference pads 114.

In addition, the chip package 110 can further include a plurality of conductors 160, respectively connected to the second reference pads 114. In this embodiment, the conductors 160 can be conductive balls. In other embodiments that are not shown, the conductors 160 can be conductive pins. Therefore, the chip 120 can be electrically connected to a part or a module of the next level through the conductors 160.

To sum up, in the above embodiments, the chip vias pass through the semiconductor substrate to directly electrically connect the reference planes of the chip to the carrier, thereby reducing the quantity of the wires for connecting the reference planes, and reducing the area of the chip. Therefore, production cost of the chip package is relatively lowered, and production speed is relatively improved. In addition, as the quantity of the wires is reduced, the length of the wire originally used to transmit the signal can be corresponding shortened, so the interference of noise and crosstalk and impedance mismatching of signal line are reduced. Further, the reference planes of the chip package can be more complete.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip package, comprising:
a carrier, having a first carrier surface;
at least one chip, having a semiconductor substrate, an interconnection structure, at least one first reference plane, at least one second reference plane, and at least one chip via, wherein the semiconductor substrate has a first substrate surface and a second substrate surface opposite to the first substrate surface, the first reference plane and the second reference plane are respectively located on the first substrate surface and the second substrate surface, the interconnection structure is located on the first reference plane and the first substrate surface and has at least one chip signal pad, and the chip via connects the first reference plane to the second reference plane;
at least one conductive bonding layer, bonding the second reference plane to the first carrier surface of the carrier;
at least one wire, connecting the chip signal pad to the first carrier surface of the carrier; and
an encapsulant, wrapping the chip and the wire.

2. The chip package as claimed in claim 1, wherein the first reference plane is a ground plane or a power plane, and the second reference plane is the ground plane or the power plane corresponding to the first reference plane.

3. The chip package as claimed in claim 1, wherein the second reference plane comprises a gold layer.

4. The chip package as claimed in claim 1, wherein the second reference plane is a composite layer comprising a Ti layer, a Cu layer, and a Ni layer.

5. The chip package as claimed in claim 1, wherein the second reference plane is a composite layer comprising a Ti layer, a Ni—V layer, and a Cu layer.

6. The chip package as claimed in claim 1, wherein the chip via passes through an internal part of the semiconductor substrate to connect the first reference plane to the second reference plane.

7. The chip package as claimed in claim 1, wherein the chip via bypasses an external side of the semiconductor substrate to connect the first reference plane to the second reference plane.

8. The chip package as claimed in claim 1, wherein the carrier has at least one carrier signal pad located on the first carrier surface of the carrier, and the wire connects the chip signal pad to the carrier signal pad.

9. The chip package as claimed in claim 1, wherein the carrier has at least one first reference pad located on the first carrier surface of the carrier, and the conductive bonding layer bonds the second reference plane to the first reference pad.

10. The chip package as claimed in claim 9, wherein the carrier has a second carrier surface opposite to the first carrier surface, at least one second reference pad, and at least one carrier via, the second reference pad is located on the second carrier surface, and the carrier via connects the first reference pad to the second reference pad.

11. The chip package as claimed in claim 10, further comprising at least one conductor connected to the second reference pad.

12. The chip package as claimed in claim 1, wherein the chip further comprises an electronic device disposed on the first substrate surface.

13. The chip package as claimed in claim 12, wherein the electronic device is electrically connected to the first reference plane through the interconnection structure.

14. The chip package as claimed in claim 12, wherein the electronic device is electrically connected to the carrier through the interconnection structure and the wire.

15. The chip package as claimed in claim 1, wherein the first reference plane is annular shaped.

16. The chip package as claimed in claim 1, wherein the second reference plane is annular shaped.
